(19) United States
(12) Patent Application Publication
(10) Pub. No.: US 2024/0312967 A1
(43) Pub. Date: Sep. 19, 2024

(54) DISPLAY PANEL

(71) Applicant: AUO Corporation, Hsinchu (TW)

(72) Inventors: Fang-Cheng Yu, Hsinchu (TW); Wen-Wei Yang, Hsinchu (TW); Cheng-Yeh Tsai, Hsinchu (TW)

(73) Assignee: AUO Corporation, Hsinchu (TW)

(21) Appl. No.: 18/675,120

(22) Filed: May 27, 2024

Related U.S. Application Data
(63) Continuation of application No. 17/338,664, filed on Jun. 4, 2021.
(60) Provisional application No. 63/035,056, filed on Jun. 5, 2020.

(30) Foreign Application Priority Data
Nov. 4, 2020 (TW) 109138355

(51) Int. Cl. H01L 25/075; H01L 25/16; H01L 33/50; H01L 33/58; H01L 33/62

(52) U.S. Cl. CPC H01L 25/0753; H01L 33/502; H01L 33/58; H01L 33/62; H01L 25/167

(57) ABSTRACT

A display panel including a substrate, a light-emitting device, a light-shielding layer, and a light-guide pillar is provided. The light-emitting device is disposed on the substrate. The light-shielding layer is disposed on the substrate and has a sidewall surrounding an opening. The light-guide pillar is disposed between the substrate and the light-emitting device and located in the opening. A gap exists between the light-guide pillar and the sidewall of the light-shielding layer.

### CROSS-REFERENCE TO RELATED APPLICATION

This application is a continuation application of and claims the priority benefit of U.S. application Ser. No. 17/338,664, filed on Jun. 4, 2021, which claims the priority benefits of U.S. provisional application Ser. No. 63/035,056, filed on Jun. 5, 2020 and Taiwan application serial no. 109138355, filed on Nov. 4, 2020. The entirety of each of the mentioned above patent applications is hereby incorporated by reference herein and made a part of this specification.

### BACKGROUND

### Technical Field

The disclosure relates to a display apparatus, and particularly to a display panel.

### Description of Related Art

In recent years, display technology and technique of manufacturing optoelectronic elements have been continuously improved, which promotes the use of the low-power, high-brightness, and long-life light-emitting diodes as display elements in display panels. In some applications, since the light-emitting-diode display panel does not need to be packaged with a sealant and thus have a narrow bezel, the light-emitting-diode display panel may be spliced into sizes to meet different application needs. However, there is still room for improvement in the luminous effect, resolution, and other characteristics of the light-emitting-diode display panel.

### SUMMARY

The present disclosure provides a display panel having good light extraction efficiency.

A display panel of an embodiment of the present disclosure includes a substrate, a light-emitting device, a light-shielding layer, and a light guide pillar. The light-emitting device is disposed on the substrate. The light-shielding layer is disposed on the substrate and has a sidewall surrounding the opening. The light guide pillar is disposed between the substrate and the light-emitting device, and is located in the opening. A gap exists between the light guide pillar and the sidewall of the light-shielding layer.

In an embodiment of the present disclosure, a light-emitting surface of the light-emitting device mentioned above faces the substrate.

In an embodiment of the present disclosure, the light refractive index of the light guide pillar mentioned above ranges from 1.5 to 2.0.

In an embodiment of the present disclosure, the width of the gap mentioned above ranges from 0.5 μm to 20 μm.

In an embodiment of the present disclosure, the display panel mentioned above further includes a positioning adhesive layer. The positioning adhesive layer is disposed on the periphery of the light-emitting device and between the light-emitting device and the light-shielding layer.

In an embodiment of the present disclosure, the light guide pillar and the positioning adhesive layer mentioned above comprise the same material.

In an embodiment of the present disclosure, the positioning adhesive layer mentioned above includes a plurality of dispersed particles.

In an embodiment of the present disclosure, the light guide pillar mentioned above includes a plurality of dispersed particles.

In an embodiment of the present disclosure, the particles mentioned above include color-conversion particles, scattered particles, or a combination thereof.

In an embodiment of the present disclosure, the particles scattering particle include quantum dot particles, phosphors, or a combination thereof.

In an embodiment of the present disclosure, the height of the light guide pillar mentioned above ranges from 1 μm to 30 μm.

In an embodiment of the present disclosure, the light guide pillar mentioned above has an inclination sidewall, and a width of the light guide pillar is greater farther away from the substrate.

In an embodiment of the present disclosure, the angle between the inclination sidewall mentioned above and a bottom surface of the light guide pillar ranges from 95 degrees to 120 degrees.

In an embodiment of the present disclosure, the sidewall of the light-shielding layer and the inclination sidewall of the light guide pillar are separated by the gap.

In an embodiment of the present disclosure, the gap mentioned above is an air gap.

In an embodiment of the present disclosure, one end of the light guide pillar mentioned above extends to a surface of the substrate.

In an embodiment of the present disclosure, the light-emitting device mentioned above includes a first pad and a pair of second pads. The pair of second pads is located on an opposite side of the first pad.

In an embodiment of the present disclosure, the light-emitting device mentioned above is a light-emitting diode.

In an embodiment of the present disclosure, the display panel mentioned above further includes a driving circuit element. The driving circuit element is disposed between the substrate and the light-shielding layer, and is electrically connected to the light-emitting device.

In an embodiment of the present disclosure, the driving circuit element mentioned above includes an active device.

Based on the above, in the display panel of the embodiments of the present disclosure, the light guide pillar is disposed between the light-emitting device and the substrate, so that the light guide pillar guides the light emitted by the light-emitting device to have a good light extraction effect.

### BRIEF DESCRIPTION OF THE DRAWINGS

FIG. 1 is a schematic partial top view of a display panel according to an embodiment of the disclosure.

FIG. 2 is a schematic cross-sectional view of the display panel of FIG. 1 along a line A-B according to some embodiments.

FIG. 3 is a schematic partial top view of a display panel according to another embodiment of the disclosure.

FIG. 4 is a schematic cross-sectional view of the display panel of FIG. 3 along a line C-D of FIG. 3 according to some embodiments.

FIG. 5 is a schematic cross-sectional view of the display panel of FIG. 3 according to other embodiments.

FIG. 6 is a schematic cross-sectional view of a display panel according to some embodiments of the disclosure.

### DESCRIPTION OF THE EMBODIMENTS

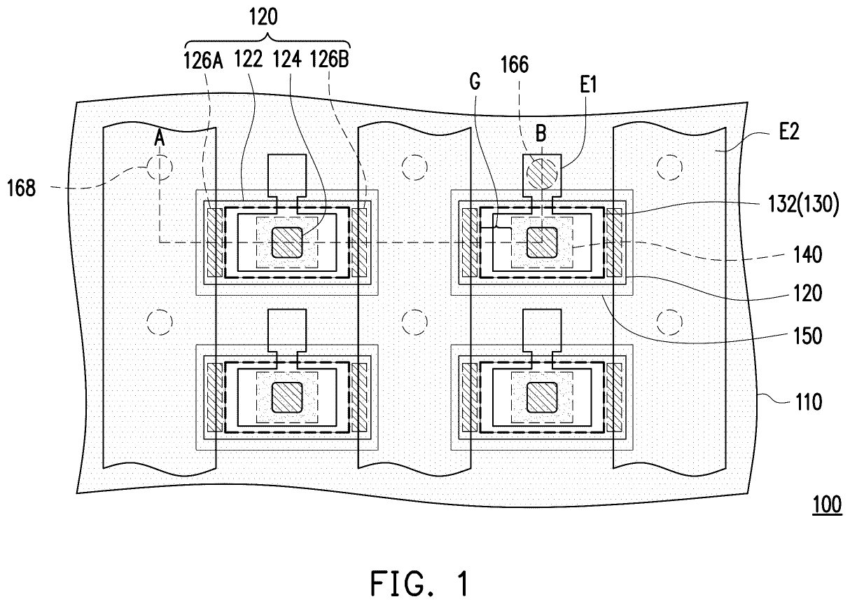

FIG. 1 is a schematic partial top view of a display panel according to an embodiment of the disclosure. In FIG. 1, a display panel 100 at least includes a substrate 110, a light-emitting device 120, a light-shielding layer 130, and a light guide pillar 140. Specifically, the light-emitting device 120, the light-shielding layer 130, and the light guide pillar 140 are all disposed on the substrate 110. There may be multiple light-emitting devices 120, and these light-emitting devices 120 are disposed in an array, but it is not limited thereto. The light-shielding layer 130 has an opening 132. In some embodiments, the area outside the opening 132 in FIG. 1 is substantially provided with the light-shielding layer 130. Therefore, for the sake of clarity, FIG. 1 only shows the outline of the opening 132 of the light-shielding layer 130. The light guide pillar 140 is located in the opening 132, and a gap G exists between the light guide pillar 140 and the opening 132. In this embodiment, the opening 132 and the light guide pillar 140 may be disposed correspondingly to the light-emitting device 120. For example, the number of the openings 132 and the number of the light guide pillars 140 may each be equal to the number of the light-emitting devices 120, and each of the light-emitting devices 120 overlaps one of the openings 132 and one of the light guide pillars 140 correspondingly. Each of the opening 132 has, for example, the shape of a ring that surrounds the periphery of the corresponding light guide pillar 140. Therefore, from the top view, the light guide pillar 140 and the light-shielding layer 130 do not overlap or contact each other.

In FIG. 1, the display panel 100 may further include a positioning adhesive layer 150. The positioning adhesive layer 150 may correspond to the peripheral configuration of the light-emitting device 120. In other words, one corresponding positioning adhesive layer 150 may be provided on the periphery of each light-emitting device 120. The positioning adhesive layer 150 may adhere the light-emitting device 120 to the substrate 110. In addition, the display panel 100 may further include a bonding electrode E1 and a bonding electrode E2 for electrically connecting to the light-emitting device 120, where the bonding electrode E2 may be shared by multiple light-emitting devices, but it is not limited thereto.

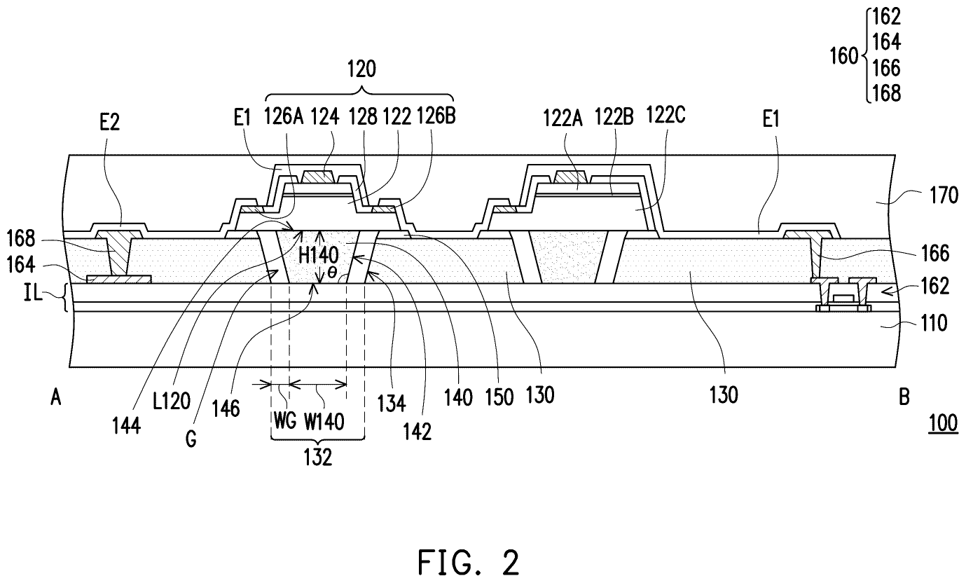

FIG. 2 is a schematic cross-sectional view of the display panel of FIG. 1 along a line A-B according to some embodiments. Please refer to FIG. 1 and FIG. 2 at the same time. The substrate 110 is, for example, a transparent substrate. In some embodiments, the substrate 110 includes a glass substrate, a quartz substrate, a plastic substrate, or other substrates with transparent properties and sufficient mechanical load-bearing properties.

The light-emitting device 120 provided on the substrate 110 is, for example, a light-emitting device that emits light in a downward direction. In other words, the light-emitting device 120 is positioned to direct a light-emitting surface L120 to face the substrate 110. The light-emitting device 120 is, for example, a light-emitting diode device. Specifically, the light-emitting device 120 may be a light-emitting device such as a millimeter light-emitting diode, a micron light-emitting diode, or the like. The light-emitting device 120 may include a semiconductor die 122, a first pad 124, a pair of second pads 126A and 126B, and a protection layer 128. The semiconductor die 122 may include a first-type semiconductor layer 122A, a light-emitting layer 122B, and a second-type semiconductor layer 122C that are sequentially stacked and singulated into the shape of an island. The width of the second-type semiconductor layer 122C may be greater than the width of the first-type semiconductor layer 122A, and the width of the light-emitting layer 122B may substantially correspond to the width of the first-type semiconductor layer 122A, but it is not limited thereto. The first pad 124 is disposed on the semiconductor die 122 and connected to the first type semiconductor layer 122A. The second pad 126A and the second pad 126B are disposed on the semiconductor die 122 and connected to the second-type semiconductor layer 122C. In addition, the second pad 126A and the second pad 126B are located on both sides of the first pad 124, which helps distribute the current flowing evenly through the light-emitting layer 122B. The protection layer 128 at least covers the sidewalls of the semiconductor die 122 to avoid unnecessary short circuits. The structure of the light-emitting device 120 in FIG. 2 is for illustrative purposes only, and does not limit the embodiments of the light-emitting device 120.

The light-shielding layer 130 is disposed on the substrate 110 and has a sidewall 134 surrounding the opening 132. The light-shielding layer 130 blocks light and includes an opaque material. In some embodiments, the material of the light-shielding layer 130 may include black photoresist or similar materials with high optical density. The area occupied by the opening 132 may be defined by the sidewall 134 and may at least overlap the light-emitting surface L120 of the light-emitting device 120. Therefore, although the light-shielding layer 130 shields light, due to the configuration of the opening 132, the light emitted by the light-emitting device 120 is still emitted toward the substrate 110 without being blocked and penetrates the substrate 110.

The light guide pillar 140 is disposed between the light-emitting device 120 and the substrate 110, and is located in the opening 132 of the light-shielding layer 130. The gap G exists between the sidewall 134 of the light-shielding layer 130 and the light guide pillar 140. In FIG. 1, the gap G completely surrounds the light guide pillar 140, that is, there is no physical contact between the light guide pillar 140 and the light-shielding layer 130. The light guide pillar 140 is, for example, located between the light-emitting surface L120 of the light-emitting device 120 and the substrate 110, and the light guide pillar 140 may contact, for example, the light-emitting surface L120 of the light-emitting device 120. In some embodiments, the light guide pillar 140 may have adhesiveness for adhering the light-emitting device 120. However, in other embodiments, the light guide pillar 140 may not have adhesiveness and only abut against the light-emitting device 120.

The light guide pillar 140 has an inclination sidewall 142. In other words, a width W140 of the light guide pillar 140 is not fixed. The sidewall 134 of the light-shielding layer 130 is, for example, also inclined, whereas the sidewall 134 of the light-shielding layer 130 and the inclination sidewall 142 of the light guide pillar 140 are not in contact with each other to maintain the gap G. A width WG of the gap G may be, for example, 0.5 μm to 20 μm. In some embodiments, the angle of inclination of the sidewall 134 and that of the inclination sidewall 142 may be the same or different.

As shown in FIG. 2, the width W140 of the light guide pillar 140 is greater farther away from the substrate 110. It can be seen from FIG. 2 that the cross-sectional structure of the light guide pillar 140 is substantially in the shape of a trapezoid. In some embodiments, the area of a top surface 144 of the light guide pillar 140 is greater than the area of a bottom surface 146 of the light guide pillar 140. The orthographic projection of the bottom surface 146 on the substrate 110 may overlap the orthographic projection of the top surface 144 on the substrate 110. And the ratio of the area of the bottom surface 146 to the area of the top surface 144 is, for example, 60% to 95%, but it is not limited thereto.

In some embodiments, the center of the top surface 144 and the center of the bottom surface 146 may be aligned with each other, but it is not limited thereto. In addition, the center of the top surface 144 may be aligned with the center of the light-emitting layer 122B, but it is not limited thereto. In some embodiments, the width of the top surface 144 of the light guide pillar 140 may be greater than the width of the light-emitting layer 122B of the light-emitting device 120. In some embodiments, the orthographic projection of the light-emitting layer 122B of the light-emitting device 120 on the substrate 110 may almost all be within the orthographic projection of the top surface 144 on the substrate 110. In addition, an included angle θ between the inclination sidewall 142 of the light guide pillar 140 and the bottom surface 146 of the light guide pillar 140 may be, for example, 95 degrees to 120 degrees, and a height H140 of the light guide pillar 140 may be greater than the thickness of the light-shielding layer 130. The height H140 of the light guide pillar 140 may be 1 μm to 30 μm, and it can be adjusted according to the light guide effect as needed.

The positioning adhesive layer 150 is disposed on the periphery of the light-emitting device 120 and is located between the light-emitting device 120 and the light-shielding layer 130. The positioning adhesive layer 150 may have adhesiveness to adhere the light-emitting device 120 to the light-shielding layer 130. In some embodiments, the light guide pillar 140 and the positioning adhesive layer 150 include the same material, so both may be adapted to attach the light-emitting device 120. For example, the light guide pillar 140 and the positioning adhesive layer 150 may both be made of photoresist material. However, in other embodiments, the light guide pillar 140 and the positioning adhesive layer 150 may include different materials. For example, the light guide pillar 140 may be made of a non-sticky photoresist material, and the positioning adhesive layer 150 may be made of a sticky photoresist material. In addition, the light guide pillar 140 may be made of a transparent photoresist material, whereas the positioning adhesive layer 150 may not be made of a transparent photoresist material. In some embodiments, multiple particles, such as quantum dot particles, phosphors, scattered particles, etc., may be dispersed in the light guide pillar 140 to provide the needed optical characteristics. The positioning adhesive layer 150 may include the particles dispersed therein, or may not include the particles.

In addition to the above components, the display panel 100 further includes a driving circuit structure 160. For example, the driving circuit structure 160 may include, but not limited to, a driving circuit element 162, a signal line 164, a conductive member 166, and a conductive member 168. The driving circuit element 162 is disposed between the substrate 110 and the light-shielding layer 130. The driving circuit element 162 may be a thin film transistor, or may include a capacitor or other circuit elements. In this embodiment, the driving circuit element 162 may be composed of multiple conductor layers and at least one semiconductor layer, and may further include an insulating layer structure IL to separate different conductor layers and semiconductor layers and/or protect the conductor layers and the semiconductor layers. The light-shielding layer 130 and the light guide pillar 140 are both disposed on the insulating layer structure IL. The signal line 164 may be disposed on the insulating layer structure IL to transmit signals (such as power signals) needed by the light-emitting device 120. The conductive member 166 and the conductive member 168 may penetrate the light-shielding layer 130 to be respectively connected to the driving circuit element 162 and the signal line 164. The bonding electrode E1 may be connected to the conductive member 166 to be electrically connected to the corresponding driving circuit element 162, and the bonding electrode E2 may be connected to the conductive member 168 to be electrically connected to the corresponding signal line 164. In this way, the driving circuit structure 160 is electrically connected to the light-emitting device 120 to control the light-emission of the light-emitting device 120.

In this embodiment, the light-emitting device 120 has a downward light-emitting structure where the light-emitting surface L120 is disposed to face the substrate 110. In this way, when viewing the image displayed by the display panel 100, the user and the light-emitting device 120 are on the opposite sides of the substrate 110 and also on the opposite sides of the light-shielding layer 130. The opening 132 of the light-shielding layer 130 at least exposes the light-emitting area of the light-emitting device 120. Therefore, the configuration of the light-shielding layer 130 does not block the light emitted by the light-emitting device 120, thereby ensuring the light-emitting efficiency of the display panel 100.

In this embodiment, the light guide pillar 140 is located between the light-emitting surface L120 and the substrate 110 and is disposed on the light-emission path of the light-emitting device 120. The light refractive index of the light guide pillar 140 ranges, for example, from 1.5 to 2.0, and the refractive index of the light guide pillar 140 may be greater than the refractive index at the gap G. In some embodiments, the gap G between the light guide pillar 140 and the light-shielding layer 130 is, for example, an air gap. In other embodiments, the gap G may be filled with a filling material, and the optical refractive index of the filling material is smaller than the optical refractive index of the light guide pillar 140. In this way, after the light emitted from the light-emitting surface L120 of the light-emitting device 120 enters the light guide pillar 140, it is totally reflected by the inclination sidewall 142 and is redirected toward the substrate 110, which helps improve the light-extraction efficiency of the display panel 100. Furthermore, in some embodiments, the display panel 100 may further include an encapsulation layer 170, and the encapsulation layer 170 covers the light-emitting device 120, the bonding electrode E1, and the bonding electrode E2. An external circuit structure (not shown) to be connected to the display panel 100, such as a driver IC, may be disposed on the encapsulation layer 170, and may be located on the back side of the light-emitting device 120 (the side opposite to the light-emitting surface L120), and be connected to the driving circuit structure 160 through a conductive structure (not shown) penetrating the encapsulation layer 170. In this way, the external circuit structure is located on the same side of the substrate 110 as the light-emitting device 120 without affecting the layout space of the light-emitting device 120 or the display effect of the display panel 100. Therefore, the density of configuring the light-emitting devices 120 may be increased as needed to have a high-resolution display effect. In addition, the display panel 100 does not need to be provided with a conductive structure penetrating the substrate 110 in order to bond the external circuit structure with the driving circuit structure 160 for driving the light-emitting devices 120, which help simplify the manufacturing process and structure design.

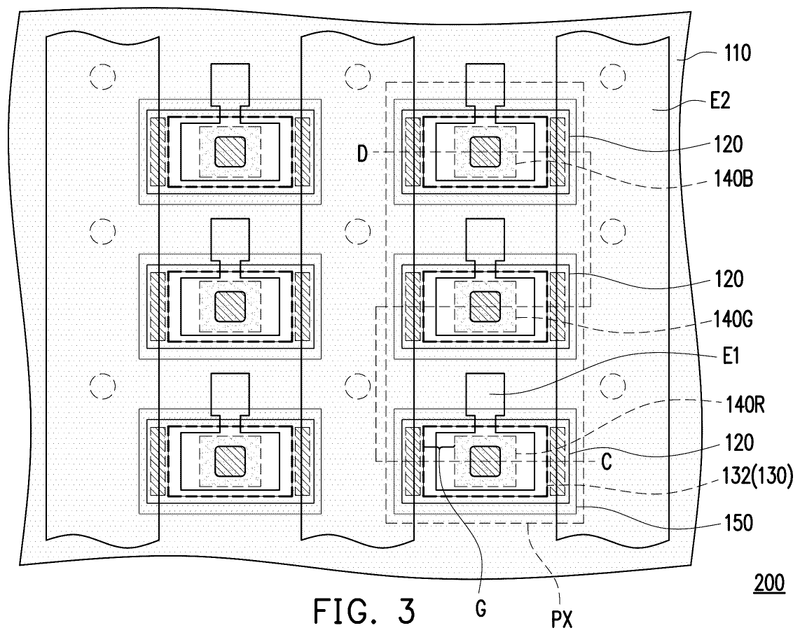

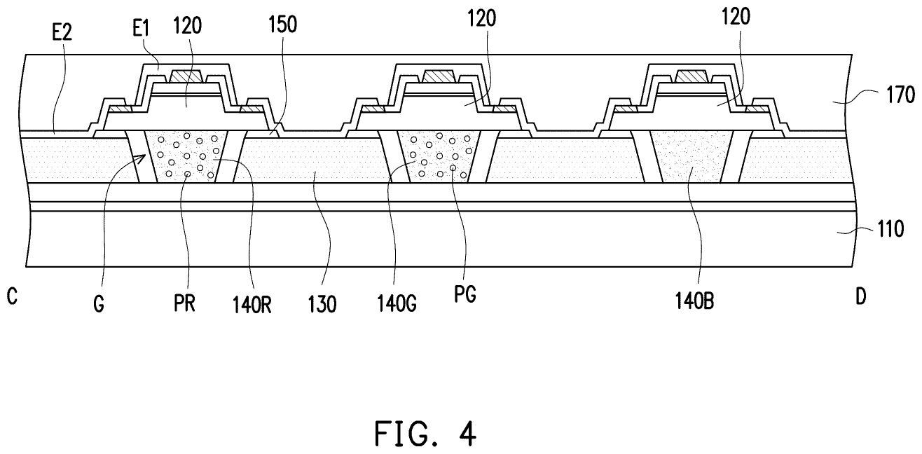

FIG. 3 is a schematic partial top view of a display panel according to another embodiment of the disclosure, and FIG. 4 is a schematic cross-sectional view of the display panel of FIG. 3 along a line C-D of FIG. 3 according to some embodiments. A display panel 200 of FIG. 3 and FIG. 4 are substantially similar to the aforementioned display panel 100, and therefore the same component symbols refer to the same or similar components. Specifically, the display panel 200 includes a substrate 110, a plurality of light-emitting devices 120, a light-shielding layer 130, a plurality of light guide pillars 140R, 140G, and 140B, a plurality of positioning adhesive layers 150, a bonding electrode E1, a bonding electrode E2, and an encapsulation layer 170, where each of the light-emitting devices 120 may be attached to the substrate 110 by one of the positioning adhesive layers 150. Here, please refer to the description of the foregoing embodiments for the arrangement of components, structure design, and material of the substrate 110, the light-emitting devices 120, the light-shielding layer 130, the positioning adhesive layers 150, the bonding electrode E1, the bonding electrode E2, and the encapsulation layer 170, as the same description is not repeated herein.

The light guide pillars 140R, 140G, and 140B are respectively disposed correspondingly to different light-emitting devices 120, and the light guide pillar 140R, the light guide pillar 140G, and the light guide pillar 140B are each separated from the light-shielding layer 130 by a gap G. In other words, the light-shielding layer 130 has a plurality of openings 132, and the light guide pillar 140R, the light guide pillar 140G, and the light guide pillar 140B are each disposed in one of the openings 132. Please refer to the foregoing embodiment for the size of the gap G. In this embodiment, the light guide pillar 140R, the light guide pillar 140G, and the light guide pillar 140B have different optical properties. For example, when the light emitted by the light-emitting device 120 is blue, the light guide pillar 140R may have a light conversion function to convert the light emitted by the light-emitting device 120 into red light; the light guide pillar 140G may have a light conversion function to convert the light emitted by the light-emitting device 120 into green light; and the light guide pillar 140B may be transparent to allow the light emitted by the light-emitting device 120 to travel through the light guide pillar 140B itself and remain blue.

In some embodiments, the light guide pillar 140R, the light guide pillar 140G, and the light guide pillar 140B may all be made of photoresist materials. The light guide pillar 140R may include a plurality of particles PR, and the particles PR may be dispersed in the entire light guide pillar 140R. The light guide pillar 140G may include a plurality of particles PG, and the particles PG may be dispersed in the entire light guide pillar 140G. The particles PR and the particles PG may include wavelength conversion particles, such as quantum dot particles, phosphors, or similar particles to provide a wavelength conversion function. In some embodiments, the particles PR and the particles PG may also include scattered particles. In other embodiments, the light guide pillar 140B may optionally further include a plurality of particles dispersed in the light guide pillar 140B that are scattered particles without the wavelength conversion function. In other words, the particles dispersed in the light guide pillar 140B do not change the color of the light emitted by the light-emitting device 120.

The particles PR in the light guide pillar 140R are, for example, a red wavelength conversion material, so the light (for example, blue light) emitted by the light-emitting device 120 is to be converted into red light after passing through the light guide pillar 140R and emitted toward the substrate 110. The particles PG in the light guide pillar 140G are, for example, a green wavelength conversion material, so the light (for example, blue light) emitted by the light-emitting device 120 is to be converted into green light after passing through the light guide pillar 140G and emitted toward the substrate 110. The light guide pillar 140B, for example, does not include wavelength conversion particles but include scattered particles without wavelength conversion, so the light (for example, blue light) emitted by the light-emitting device 120 remains blue after passing through the light guide pillar 140B. In this way, the light guide pillar 140R, the light guide pillar 140G, and the light guide pillar 140B, and the three corresponding light-emitting devices 120 may form a display pixel PX, which may be adapted to display color images.

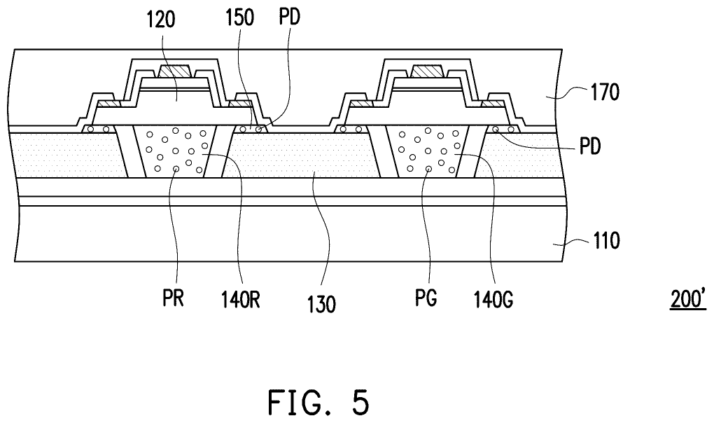

FIG. 5 is a schematic cross-sectional view of the display panel of FIG. 3 according to other embodiments. A display panel 200′ of FIG. 5 is substantially the same as the display panel 200 of FIG. 4. Therefore the same component symbols in the two figures refer to the same or similar components, such that the same description does not repeat herein. Specifically, the display panel 200′ includes a substrate 110, a light-emitting device 120, a light-shielding layer 130, a light guide pillar 140R, a light guide pillar 140G, a positioning adhesive layer 150, and an encapsulation layer 170. Please refer to the previous description of the foregoing embodiments for the arrangement of components, structure design, and material of these components. The positioning adhesive layer 150 of this embodiment further includes a plurality of particles PD, and the particles PD are dispersed in the positioning adhesive layer 150. The particles PD in the positioning adhesive layer 150 may be the same as the particles PR in the light guide pillar 140R and/or the particles PG in the light guide pillar 140G. In some embodiments, a plurality of particles (for example, diffusion particles without the light conversion function) may be dispersed in the light guide pillar 140B, and the particles PD in the positioning adhesive layer 150 may be the same as the particles in the light guide pillar 140B.

In some embodiments, the positioning adhesive layer 150 corresponding to the light guide pillar 140R is made of the material of the light guide pillar 140R, the positioning adhesive layer 150 corresponding to the light guide pillar 140G is made of the material of the light guide pillar 140G, and the positioning adhesive layer 150 corresponding to the light guide pillar 140B is made of the material of the light guide pillar 140B. In this way, the materials of different positioning adhesive layers 150 may be different. However, this disclosure is not limited thereto. In other embodiments, all the positioning adhesive layers 150 may also be selectively the same as the particles PR in the light guide pillar 140R, the particles PG in the light guide pillar 140G, or the particles (if any) in the light guide pillar 140B. In other words, the positioning adhesive layers 150 corresponding to different light guide pillars 140R, 140B, and 140B may include the same type of the particles PD.

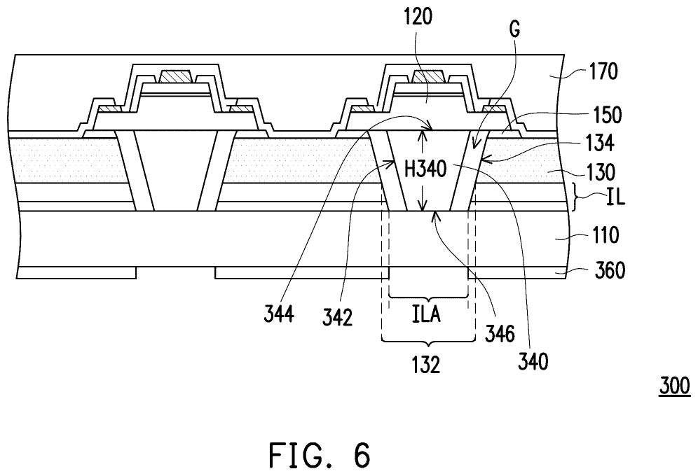

FIG. 6 is a schematic cross-sectional view of a display panel according to some embodiments of the disclosure. A display panel 300 of FIG. 6 is substantially similar to the display panel 100 of FIG. 2. Therefore the same component symbols in the two figures refer to the same or similar components, such that the same description does not repeat herein. In this embodiment, the display panel 300 mainly includes a substrate 110, a light-emitting device 120, a light-shielding layer 130, a light guide pillar 340, a positioning adhesive layer 150, an encapsulation layer 170, and an outer optical layer 360. Here, please refer to the description of the foregoing embodiments for the arrangement of components, structure design, and material of the substrate 110, the light-emitting device 120, the light-shielding layer 130, and the positioning adhesive layer 150 in FIG. 1.

The light guide pillar 340 has a trapezoidal structure in cross section, including an inclination sidewall 342, a top surface 344 and a bottom surface 346. The inclination sidewall 342 and the sidewall of the light-shielding layer 130 defining the opening 132 are separated by a gap G, so that the light guide pillar 340 does not contact the light-shielding layer 130. The top surface 344 of the light guide pillar 340 may contact the light-emitting device 120, and the bottom surface 346 of the light guide pillar 340 may contact the substrate 110. In addition, an insulating layer structure IL provided on the substrate 110 may have a hollow area ILA corresponding to the opening 132, so that the light guide pillar 340 may be located in the hollow area ILA. In this way, a height H340 of the light guide pillar 340 may be, for example, approximately equal to the distance from the light-emitting device 120 to the substrate 110. In other words, there is no other member or film (such as the insulating layer structure IL) between the light guide pillar 340 and the substrate 110, which helps improve the light extraction efficiency of the display panel 300. For example, since the light guide pillar 340 directly contacts the substrate 110, the light emitted by the light-emitting device 120 can directly reach the substrate 110 after passing through the light guide pillar 340, thereby reducing the light loss.

In addition, in this embodiment, the display panel 300 includes the outer optical layer 360 which is disposed on the outer side of the substrate 110. The outer optical layer 360 is disposed between the user and the substrate 110. In some embodiments, the outer optical layer 360 includes a patterned light-shielding layer, an anti-reflection layer, or a circular-polarization layer. The configuration of the outer optical layer 360 helps prevent the components in the display panel 300 from reflecting external light and interfering with the display effect of the display panel 300. When the outer optical layer 360 is a patterned light-shielding layer, the area of the orthographic projection of the outer optical layer 360 on the substrate 110 may substantially overlap the area of the orthographic projection of the light-shielding layer 130 on the substrate 110. The outer optical layer 360 of this embodiment may be optionally applied to any one of the display panels 100 and 200 of the foregoing embodiments.

In any of the above embodiments, the display panels 100, 200, and 300 adopt a light-emitting device 120 that emits light in a downward direction, so the display panels 100, 200, and 300 do not need to be provided with sealant for the display medium, which helps reduce the width of the bezel, and may even a design without bezel. The display panels 100, 200, and 300 are provided with a light-shielding layer 130 having an opening 132 and a light guide pillar 140, 140R, 140G, 140B, or 340 located in the opening 132. The light guide pillar 140, 140R, 140G, 140B or 340 is separated from the light-shielding layer 130, which allows the light guide pillar 140, 140R, 140G, 140B, or 340 between the light-emitting device 120 and the substrate 110 to provide the light guide function. Therefore, the display panels 100, 200, and 300 may have ideal light extraction efficiency.

In addition, when the display panels 100, 200, and 300 need to be connected to an external circuit structure such as a driver IC, the external circuit structure may be bonded to the back side of the light-emitting device 120 (the side opposite to the light-emitting surface L120). In this way, the external circuit structure is located on the same side of the substrate 110 as the light-emitting device 120 without affecting the layout space of the light-emitting device 120 or the display effects of the display panels 100, 200, and 300. Therefore, the density of configuring the light-emitting devices 120 may be increased as needed to achieve a high-resolution display effect. In addition, the display panels 100, 200, and 300 do not need to provide a conductive structure penetrating the substrate 110 in order to bond the external circuit structure with the driving circuit structure 160 for driving the light-emitting device 120, which helps simplify the manufacturing process and structural design.

In summary. the display panel of the embodiments of the present disclosure has ideal light extraction efficiency, a narrow bezel. and a simplified structural design.

What is claimed is:

1. A display panel, comprising:
a substrate;
a light-emitting device, disposed on the substrate;
a light-shielding layer, disposed on the substrate and has a sidewall surrounding an opening; and
a light guide pillar, disposed between the substrate and the light-emitting device, and located in the opening, wherein a gap exists between the light guide pillar and the sidewall of the light-shielding layer, and the gap physically contacts with the light-emitting device; and
a driving circuit element, electrically connected to the light-emitting device, wherein the driving circuit element is disposed between the substrate and the light-shielding layer;
a normal projection of a light-emitting layer of the light-emitting device on the substrate is located within a normal projection of a top surface of the light guide pillar on the substrate;
the light guide pillar has an inclination sidewall, and a width of the light guide pillar is greater farther away from the substrate.

2. The display panel according to claim 1, wherein a light-emitting surface of the light-emitting device faces the substrate.

3. The display panel according to claim 1, wherein a light refractive index of the light guide pillar ranges from 1.5 to 2.0.

4. The display panel according to claim 1, wherein a width of the gap ranges from 0.5 μm to 20 μm.

5. The display panel according to claim 1, further comprising a positioning adhesive layer disposed on a periphery of the light-emitting device and between the light-emitting device and the light-shielding layer.

6. The display panel according to claim 5, wherein the light guide pillar and the positioning adhesive layer comprise a same material.

7. The display panel according to claim 5, wherein the positioning adhesive layer comprises a plurality of dispersed particles.

8. The display panel according to claim 1, wherein the light guide pillar comprises a plurality of dispersed particles.

9. The display panel according to claim 8, wherein the particles comprise color-conversion particles, scattered particles, or a combination thereof.

10. The display panel according to claim 8, wherein the particles comprise quantum dot particles, phosphors, or a combination thereof.

11. The display panel according to claim 1, wherein a height of the light guide pillar ranges from 1 μm to 30 μm.

12. The display panel according to claim 1, wherein an angle between the inclination sidewall and a bottom surface of the light guide pillar ranges from 95 degrees to 120 degrees.

13. The display panel according to claim 1, wherein the sidewall of the light-shielding layer and the inclination sidewall of the light guide pillar are separated by the gap.

14. The display panel according to claim 1, wherein the gap is an air gap.

15. The display panel according to claim 1, wherein one end of the light guide pillar extends to a surface of the substrate.

16. The display panel according to claim 1, wherein the light-emitting device comprises a first pad and a pair of second pads, and the pair of second pads is located on an opposite side of the first pad.

17. The display panel according to claim 1, wherein the light-emitting device is a light-emitting diode.

18. The display panel according to claim 1, wherein the driving circuit element comprises an active device.

19. The display panel according to claim 1, wherein the gap directly and physically contacts with the light-emitting device.

20. The display panel according to claim 1, wherein a normal projection of a bottom surface of the light guide pillar on the substrate and a normal projection of the top surface of the light guide pillar on the substrate are overlapped.
